(19) United States
(12) Patent Application Publication
(10) Pub. No.: US 2011/0006788 A1
(43) Pub. Date: Jan. 13, 2011

(54) OCCUPANT CLASSIFICATION SYSTEM FOR VEHICLE

(75) Inventors: Kyu Jong Kim, Gyeonggi-do (KR); Chun Seok Park, Gyeonggi-do (KR); Tae In Kim, Gyeonggi-do (KR); Hyeong Ho Choi, Gyeonggi-do (KR)

Correspondence Address: EDWARDS ANGELL PALMER & DODGE LLP, P.O. BOX 55874, BOSTON, MA, 02205, US

(73) Assignees: HYUNDAI MOTOR COMPANY, Seoul (KR); KIA MOTORS CORPORATION, Seoul (KR)

(21) Appl. No.: 12/630,958

(22) Filed: Dec. 4, 2009

(30) Foreign Application Priority Data
Jul. 13, 2009 (KR) 10-2009-0063557

(51) Int. Cl. G01R 27/26

(52) U.S. Cl. 324/661

(57) ABSTRACT

The present invention features an occupant classification system for a vehicle. Preferably, the occupant classification system includes a heater located below a seat cover; and an occupant classification sensor provided above the heater to detect an occupant. Preferably, the occupant classification sensor includes two electrodes arranged in parallel to each other on one plane.

### CROSS REFERENCE TO RELATED APPLICATION

The present application claims priority to Korean Patent Application Number 10-2009-0063557 filed on Jul. 13, 2009, the entire contents of which is incorporated herein by reference in its entirety.

### BACKGROUND OF THE INVENTION

### Field of the Invention

The present invention relates, generally, to an occupant classification system for a vehicle, and more particularly, to an arrangement of an occupant classification system provided in a vehicle seat in which the ability of a sensor to classify an occupant can be improved and the performance of an adjacent heater can be improved.

In general, a vehicle is preferably equipped with a variety of devices in order to ensure occupant safety and promote a comfortable environment. For example, an air bag for protecting an occupant from an unexpected accident or impact is preferably installed inside a steering wheel or a dashboard in front of the driver's seat or the seat next to the driver. Preferably, the air bag deploys towards the occupant in response to an impact to thereby protect the occupant from the impact.

In order to meet Federal Motor Vehicle Safety Standard (FMVSS) 208, occupant classification sensors, which classify a child (e.g., one-, three-, or six-year-old child) or a child's seat from an adult occupant on the seat next to the driver, have been provided. Recently, more air bags are following Low Risk Deployment (LRD) standard for 3- and 6-year-old children. Further, occupant classification sensors that are capable of classifying a Child Restraint System (CRS) for one-year-old child from an adult occupant are currently under development.

FIG. 1 is a perspective view illustrating an exemplary configuration of a conventional occupant classification system installed in a vehicle seat. FIG. 2 is a cross-sectional view illustrating key parts of FIG. 1.

Preferably, as shown in FIG. 1, an occupant classification sensor 110 of the occupant classification system is suitably provided under a seat cover C, and a heater 120 is suitably provided below the occupant classification sensor 110 to heat a seat S.

Preferably, as shown in FIG. 2, the occupant classification sensor 110 includes upper and lower electrodes 111 and 113 that are suitably arranged in parallel to each other and a spacer 115 interposed between the electrodes 111 and 113, and is preferably located above the heater 120. Preferably, the occupant classification sensor 110 suitably detects contact status of an occupant in contact with the cover C of the seat S based on a change in an electric field generated by the electrodes 111 and 113, and sends contact status information to an Electronic Control Unit (ECU).

Preferably, the electrode 113 adjacent to the heater 120 is provided with a shield in order to suitably protect the occupant classification sensor 120 from the electric field of the heater 110.

However, the conventional occupant classification system installed in the vehicle seat does not properly classify the type of occupant since the occupant classification sensor 110 is thick due to the two-layer structure of the upper and lower electrodes and the shield. Accordingly, the thickness of the occupant classification sensor 120 causes the heater 110 located below to be spaced farther apart from the cover C of the seat S, and therefore degradation in the performance of the heater 120 may occur.

Further, the occupant classification sensor 110 may have decreased endurance due to short-circuiting or deformation since the seat S is exposed to water and/or liquid.

The information disclosed in this Background section is only for enhancement of understanding of the background of the invention and should not be taken as an acknowledgment or any form of suggestion that this information forms the prior art that is already known to a person skilled in the art.

### SUMMARY OF THE INVENTION

The present invention preferably provides an occupant classification system for a vehicle preferably provided in a vehicle seat, in which an occupant classification sensor has a suitably improved ability to classify an occupant and a suitably enhanced endurance, and a heater that has suitably improved performance.

In a preferred embodiment of the present invention, the occupant classification system for a vehicle may include a heater that is preferably located below a seat cover; and an occupant classification sensor provided above the heater to suitably detect an occupant. Preferably, the occupant classification sensor includes two electrodes arranged in parallel to each other on one plane.

In certain preferred embodiments, the electrodes of the occupant classification sensor can be first and second sensors, preferably each of which has a recess and a protrusion.

In other preferred embodiments, the protrusion of the first electrode can be two protrusions. In further preferred embodiments, the protrusion of the first electrode can be three protrusions.

Further, preferably the protrusion of the first electrode and the recess of the second electrode are suitably arranged to be adjacent to and oppose each other.

According to preferred exemplary embodiments of the present invention, the occupant classification system has the following effects:

In one preferred embodiment, since the two electrodes of the occupant classification sensor are suitably arranged in parallel to each other on the same plane, the occupant classification sensor can be suitably designed to be thin with improved ability to classify an occupant.

In another preferred embodiment, since the electric field generated by the two parallel electrodes is suitably limited to only the top surface of the seat, the ability to classify an occupant can be suitably improved and the electrodes are not required to be shielded. Further, Electro-Magnetic Interference (EMI) shielding and Electro-Magnetic Susceptibility (EMS) can be suitably improved.

In another further embodiment, since the occupant classification sensor can preferably be designed to be thin and flexible, it can overcome conventional problems such as deterioration in endurance due to short-circuiting of electrodes.

In still another preferred embodiment, the distance between the seat cover and the heater, and the performance of the heater can be improved.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum).

As referred to herein, a hybrid vehicle is a vehicle that has two or more sources of power, for example both gasoline-powered and electric-powered.

The above features and advantages of the present invention will be apparent from or are set forth in more detail in the accompanying drawings, which are incorporated in and form a part of this specification, and the following Detailed Description, which together serve to explain by way of example the principles of the present invention.

### BRIEF DESCRIPTION OF THE DRAWINGS

The above and other features of the present invention will now be described in detail with reference to certain exemplary embodiments thereof illustrated by the accompanying drawings which are given hereinafter by way of illustration only, and thus are not limitative of the present invention, and wherein:

FIG. 1 is a perspective view illustrating an exemplary configuration of a conventional occupant classification system installed in a vehicle seat;

FIG. 2 is a cross-sectional view illustrating key parts of FIG. 1;

FIG. 3 is a perspective view illustrating an exemplary configuration of an occupant classification system for a vehicle according to an exemplary embodiment of the invention;

FIG. 4 is a top plan view illustrating the occupant classification system for a vehicle shown in FIG. 3 according to preferred embodiments of the present invention;

FIG. 5 is a conceptual view illustrating the relation between a distance of electrode plates and a sensible distance; and

FIG. 6 is a top plan view illustrating the configuration of an occupant classification system for a vehicle according to another exemplary embodiment of the invention.

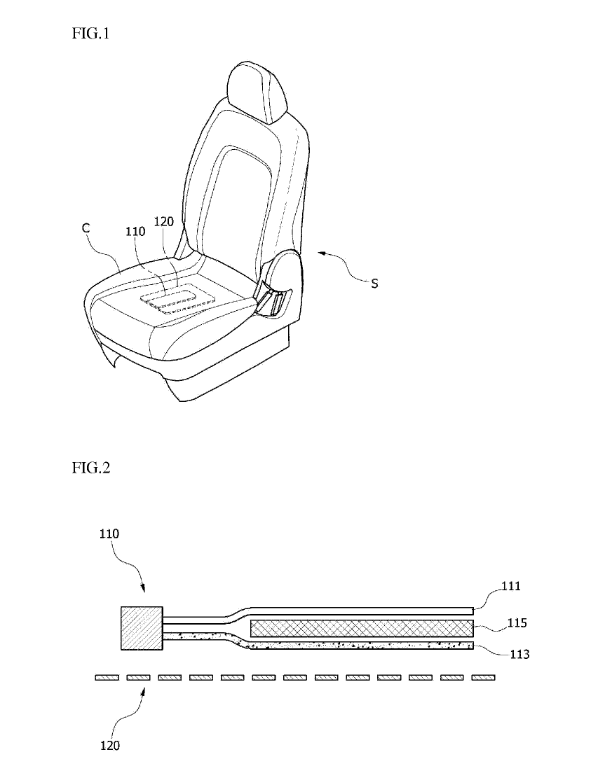

### DETAILED DESCRIPTION OF THE INVENTION

As described herein, the present invention includes an occupant classification system for a vehicle comprising a heater; and an occupant classification sensor, wherein the occupant classification sensor includes one or more electrodes.

In one embodiment, the heater is located below a seat cover.

In another embodiment, the occupant classification sensor is provided above the heater to detect an occupant.

In another further embodiment, the occupant classification sensor includes two electrodes.

In another related embodiment, the sensors are arranged in parallel to each other on one plane.

In still another further embodiment, the electrodes of the occupant classification sensor comprise first and second sensors, wherein each sensor has a recess and a protrusion.

In another related embodiment, the protrusion of the first electrode comprises two or more protrusions.

In a further related embodiment, the protrusion of the first electrode comprises three or more protrusions.

Reference will now be made in detail to various embodiments of the present invention(s), examples of which are illustrated in the accompanying drawings and described below. While the invention(s) will be described in conjunction with exemplary embodiments, it will be understood that present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims. Reference should be made to the drawings, in which the same reference numerals and signs are used throughout the different drawings to designate the same or similar components.

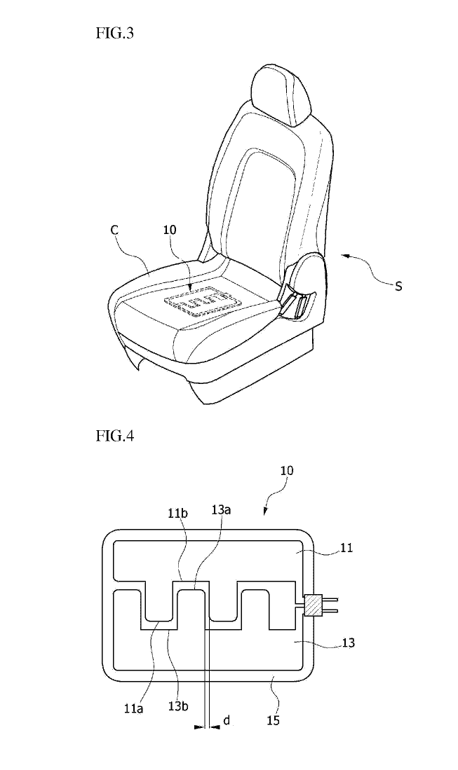

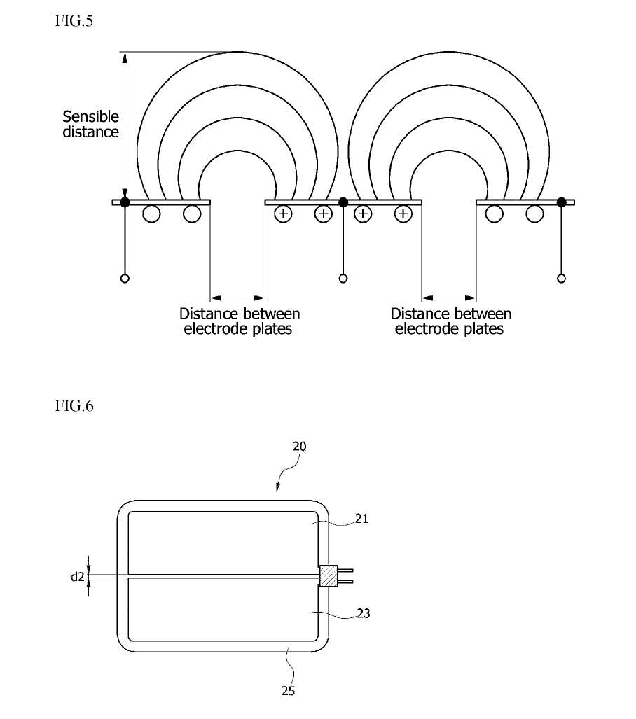

FIG. 3 is a perspective view illustrating the configuration of an occupant classification system for a vehicle according to an exemplary embodiment of the invention. FIG. 4 is a top plan view illustrating an exemplary occupant classification system for a vehicle shown in FIG. 3. FIG. 5 is a conceptual view illustrating the relation between an the distance of electrode plates and a sensible distance.

In certain preferred embodiments of the present invention, and as shown in FIG. 3, the occupant classification system for a vehicle can be suitably installed inside a back or below a cover C of a seat S. According to exemplary embodiments of the present invention, and for convenience of the description herein, the occupant classification system for a vehicle is described as being installed below the cover C of the seat S. In further preferred embodiments, a heater (not shown) is suitably installed below the occupant classification system to heat the seat S.

According to certain exemplary embodiments of the present invention, the occupant classification system is generally divided according to occupant classification sensor types. Preferably, the occupant classification system is suitably divided into a pattern classification type that suitably classifies an occupant on the seat next to the driver based on the hip pattern of the occupant; a strain gauge type that suitably detects a pressure on the seat next to the driver, caused by the weight of the occupant, preferably using a variable resistor; a hydraulic type that suitably detects a pressure applied to a bag in which silicone is contained; and a capacitance type that suitably measures a capacitance variance according to the occupant on the seat next to the driver.

Preferably, the occupant classification system of this embodiment includes an occupant classification sensor 10, which is suitably located above the heater. According to preferred embodiments of the present invention, the occupant classification sensor 10 suitably serves to detect an occupant in contact with the cover C based on a change in an electric field. In further preferred embodiments, the occupant classification sensor 10 preferably includes plate-like first and second electrodes 11 and 13 and a bottom plate 15, and suitably detects the occupant by sensing a change in the dielectric constant of the electric field that is generated between the two electrodes 11 and 13. Preferably, the bottom plate 15 suitably maintains the configuration of the first and second electrodes 11 and 13 so that the first or second electrode 11 or 13 does not interfere with the heater below.

According to further preferred embodiments and as shown in FIG. 4, the occupant classification sensor 10 is suitably implemented with a capacitor sensor, with the first and second electrodes 11 and 13 preferably arranged in parallel to each other on the same plane. Preferably, this configuration is different from the conventional occupant classification sensor 110 (see FIG. 2) in which the electrodes are vertically arranged into two layers. Accordingly, as a result, this provides an effect that can considerably reduce the thickness of the occupant classification sensor 10. In further preferred embodiments, the first and second electrodes 11 and 13 can suitably exchange dielectric constant information between areas in the seat S, thereby improving the ability to classify an occupant.

According to certain exemplary embodiments, the first electrode 11 of the occupant classification sensor 10 has two protrusions 11a and alternating recesses 11b. In further preferred embodiments, like the first electrode 11, the second electrode 13 preferably has two protrusions 13a and alternating recesses 13b. Preferably, the first and second electrodes 11 and 13 are suitably arranged in such a fashion that the protrusions 11a and the recesses 13b are adjacent to and oppose each other. Preferably, in other further embodiments, the first and second electrodes 11 and 13 are suitably arranged in such a fashion that the protrusions 13a and the recesses 11b are adjacent to and oppose each other.

Preferably, this configuration can suitably increase the adjacent areas between the first and second electrodes 11 and 13 while suitably decreasing intervals d between the first and second electrodes 11 and 13.

Accordingly, in preferred embodiments of the present invention, a sensible distance can be suitably adjusted by properly changing the interval d, which is the distance between the electrode plates. FIG. 5 illustrates the relation between the distance of the electrode plates and an exemplary sensible distance. Preferably, the sensible distance is determined by an electric field suitably generated by two adjacent electrodes.

As described herein, the occupant classification sensor 10 of the present invention can suitably reduce the sensible distance while suitably increasing the sensing area. Preferably, this is because the interval d decreases in inverse proportion to an increase in the adjacent areas of the first and second electrodes 11 and 13, thereby suitably improving sensitivity and accuracy as well as the ability to suitably classify an occupant.

Preferably, the occupant classification system for detecting an occupant on a vehicle seat of the present invention can suitably reduce the thickness of the occupant classification sensor while suitably improving the ability to classify an occupant since the two electrodes of the occupant classification sensor are suitably arranged in parallel to each other on the same plane.

Further, since the electric field generated by the two parallel electrodes is suitably limited to only the top surface of the seat, and the electric field generated by the heater is suitably reduced by positive and negative poles of the occupant classification sensor, it is preferably not required to shield the electrodes. Accordingly, in further preferred embodiments of the present invention, Electro-Magnetic Interference (EMI) shielding and Electro-Magnetic Susceptibility (EMS) can be suitably improved, for example even if a mobile phone is placed on the seat or the heater is in operation.

According to preferred embodiments of the present invention, since the occupant classification sensor can be suitably designed to be thin and flexible, it can suitably overcome conventional problems such as deterioration in endurance due to the short-circuiting of the electrodes. Further, the performance of the heater can be suitably improved since the distance between the seat cover and the heater is suitably reduced.

Further, when one of the first and second electrodes is suitably damaged, sensing can still be enabled by grounding the other electrode.

In one exemplary embodiment, the applicant of the present invention tested the ability to classify an occupant and the effect on the heater by employing the occupant classification system having the occupant classification sensor in accordance with preferred embodiments of the present invention. The results of these experiments showed the ability to classify an occupant and EMI shielding and EMS characteristics with an improvement over known methods.

FIG. 6 is a top plan view illustrating the configuration of an occupant classification system for a vehicle according to another exemplary embodiment of the invention.

Here, a first electrode 21 and a second electrode 23, each of which has a suitably rectangular shape, are preferably arranged adjacent to each other on the same plane such that only one interval d2 is suitably defined between the electrodes 21 and 23. In further preferred embodiments, a bottom plate 25 can also be suitably arranged below the first and second electrodes 21 and 23.

Preferably, since the first and second electrodes can be suitably arranged on the same plane, they can have a variety of shapes such as, but not only limited to, a quadrangle, a triangle, an ellipse, and a circle unlike the foregoing embodiment. In further preferred embodiments, the first and second electrodes can have different shapes that do not suitably conform to each other.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. An occupant classification system for a vehicle comprising:
a heater located below a seat cover; and
an occupant classification sensor provided above the heater to detect an occupant,
wherein the occupant classification sensor includes two electrodes arranged in parallel to each other on one plane.

2. The occupant classification system in accordance with claim 1, wherein the electrodes of the occupant classification sensor comprise first and second sensors, each of which has a recess and a protrusion.

3. The occupant classification system in accordance with claim 2, wherein the protrusion of the first electrode comprises two protrusions, and the protrusion of the first electrode comprises three protrusions.

4. The occupant classification system in accordance with claim 3, wherein the protrusion of the first electrode and the recess of the second electrode are arranged to be adjacent to and oppose each other.

5. The occupant classification system in accordance with claim 2, wherein the protrusion of the first electrode and the recess of the second electrode are arranged to be adjacent to and oppose each other.

6. An occupant classification system for a vehicle comprising:
a heater; and
an occupant classification sensor,
wherein the occupant classification sensor includes one or more electrodes.

7. The occupant classification system for a vehicle of claim 6, wherein the heater is located below a seat cover.

8. The occupant classification system for a vehicle of claim 6, wherein the occupant classification sensor is provided above the heater to detect an occupant.

9. The occupant classification system for a vehicle of claim 6, wherein the occupant classification sensor comprises two electrodes.

10. The occupant classification system for a vehicle of claim 6, wherein the sensors are arranged in parallel to each other on one plane.

11. The occupant classification system for a vehicle of claim 6, wherein the electrodes of the occupant classification sensor comprise first and second sensors, wherein each sensor has a recess and a protrusion.

12. The occupant classification system for a vehicle of claim 11, wherein the protrusion of the first electrode comprises two or more protrusions.

13. The occupant classification system for a vehicle of claim 11, wherein the protrusion of the second electrode comprises three or more protrusions.
